(19) United States
(12) Patent Application Publication
(10) Pub. No.: US 2013/0234171 A1
(43) Pub. Date: Sep. 12, 2013

(54) METHOD AND SYSTEM FOR FORMING INTEGRATED LIGHT GUIDES

(71) Applicant: TACTOTEK OY, Oulu (FI)

(72) Inventors: Mikko Heikkinen, Oulu (FI); Antti Keranen, Oulu (FI); Juha Salo, Littoinen (FI)

(73) Assignee: TACTOTEK OY, Oulu (FI)

(21) Appl. No.: 13/787,860

(22) Filed: Mar. 7, 2013

(30) Foreign Application Priority Data
Mar. 8, 2012 (GB) 1204062.2

(51) Int. Cl. H01L 33/58

(52) U.S. Cl. CPC H01L 33/58
USPC 257/88; 438/27; 118/300

(57) ABSTRACT

A method and a system for forming one or more integrated light guides comprising one or more light sources and one or more light transmissive materials are disclosed. At least one of the one or more light transmissive materials is capable of transmitting light emitted by at least one of the one or more light sources. The method includes disposing the one or more light sources on one or more sides of a substrate to form an arrangement of the one or more light sources. Additionally, the method includes molding the one or more light transmissive materials onto one or more parts of one or more sides of the arrangement of the one or more light sources to form the one or more integrated light guides.

### CROSS-REFERENCE TO RELATED APPLICATIONS

This application claims priority to United Kingdom Patent Application No. 1204062.2, filed on 8 Mar. 2012, the entire content of which is incorporated herein by reference.

### FIELD OF THE INVENTION

The present invention relates to methods of forming one or more integrated light guides comprising one or more light sources and one or more light transmissive materials, wherein at least one of the one or more light transmissive materials is capable of transmitting light emitted by at least one of the one or more light sources. The present invention also relates to a system for forming one or more integrated light guides comprising one or more light sources and one or more light transmissive materials, wherein at least one of the one or more light transmissive materials is capable of transmitting light emitted by at least one of the one or more light sources. Moreover, the present invention also relates to one or more integrated light guides formed by aforementioned methods.

### BACKGROUND

Light guides have been extensively used in a wide range of applications where light emanating from one or more light sources is required to be guided to form a predetermined spatial pattern of light distribution. For example, in some applications there is a need to form a substantially uniform distribution of light over a spatial region by utilizing one or more point light sources, such as Light Emitting Diodes (LEDs). One such application is in non-emissive display devices, such as a Liquid Crystal Display (LCD) device, where there is a need to produce a substantially uniform distribution of light over a planar region in order to illuminate the LCD device. The substantially uniform distribution of light is formed by an arrangement comprising one or more point light sources and a light guide. The arrangement is commonly referred to as being a backlight of the LCD device.

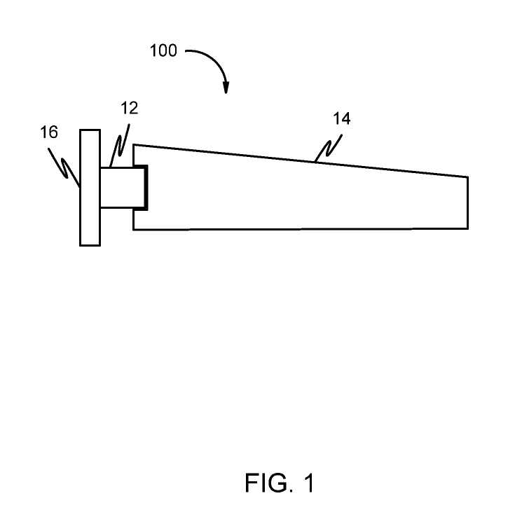

Conventionally, the arrangement of one or more light sources and a light guide is formed by assembling the one or more light sources with a light guide, wherein each of the light guide and the one or more light sources are separately manufactured as discrete components. For example, FIG. 1 illustrates a side view of a conventional arrangement 100 of one or more light sources 12 and a light guide 14. The one or more light sources 12 may be, for example, LEDs. The arrangement 100 comprises a Printed Circuit Board (PCB) 16 onto which the one or more light sources 12 are fabricated using conventional electronics manufacturing techniques. The PCB 16 may include one or more of a conductor, an electronic circuit and a connector for providing an electrical interface between the one or more light sources 12 and one or more of a power source and a control circuit. The arrangement 100 shown in FIG. 1 is formed by separately manufacturing the light guide 14 from a light transmissive material, such as acrylic, and subsequently attaching the light guide 14 to the one or more light sources 12 by using an adhesive material.

This conventional method of forming the arrangement 100 of the one or more light sources 12 and the light guide 14 results in large manufacturing costs. Moreover, this method results in a large attenuation of light transmitted from the one or more light sources 12 due to the formation of multiple boundaries along the path of transmission of light from the one or more light sources 12 into the light guide 14. Furthermore, when assembling a plurality of arrangements of the one or more light sources 12 and the light 14, the total area of illumination produced is less due to the discrete nature of the one or more light sources 12 and the light guide 14. Moreover, there is a possibility of occurrence of misalignment between the one or more light sources 12 and the light guide 14 during one or more of manufacturing, transportation, handling and usage of the arrangement 100 of one or more light sources 12 and the light guide 14. Accordingly, there is a need for improved methods and systems of forming the arrangement of one or more light sources 12 and the light guide 14.

In a published US patent application no. US20071115687 (VERWEG), “Light emitting unit and method of producing the same”, there is described a light emitting unit with a solid state light source mounted on a lead-frame and a light guide. The solid state light and at least part of the lead-frame are moulded with a moulded material. This moulded material forms at least a part of the light guide, but displays similar draw backs described previously for conventional methods of producing the same.

### SUMMARY

The various embodiments of the present invention seeks to provide an improved method of forming one or more integrated light guides comprising one or more light sources and one or more light transmissive materials.

The various embodiments of the present invention also seeks to provide an improved system of forming one or more integrated light guides comprising one or more light sources and one or more light transmissive materials.

The various embodiments of the present invention additionally seeks to provide an improved integrated light guide comprising one or more light sources and one or more light transmissive materials.

According to a first aspect, there is provided a method of forming one or more integrated light guides comprising one or more light sources and one or more light transmissive materials. At least one of the one or more light transmissive materials is capable of transmitting light emitted by at least one of the one or more light sources. The method includes disposing the one or more light sources on one or more sides of a substrate to form an arrangement of the one or more light sources. Additionally, the method includes molding the one or more light transmissive materials onto one or more parts of one or more sides of the arrangement of the one or more light sources to form the one or more integrated light guides. Further, the method is performed utilizing a continuous manufacturing process.

One advantage of the embodiment is that it minimizes the manufacturing costs of forming the one or more integrated light guides. Another advantage of the embodiment is that the one or more integrated light guides minimize attenuation to light transmitted from the one or more light sources into the one or more light transmissive materials, for example, by reducing effects of optical boundaries. Yet another advantage of the embodiment is that the one or more integrated light guides are mechanically robust and minimize the possibility of occurrence of misalignment between the one or more light sources and the one or more light transmissive materials during one or more of manufacturing, transportation, handling and usage of the one or more integrated light guides. Still yet another advantage of the embodiment is that an assembly of a plurality of the one or more integrated light guides provides a large area of illumination.

Optionally, the one or more light sources include one or more of a Light Emitting Diode (LED), an Organic Light Emitting Diode (OLED), an Organic Light Emitting Transistor (OLET) and a laser diode. Optionally, the one or more light sources include nanostructures, for example, Zinc Oxide nanowires, which can convert electrical power to optical power with a conversion efficiency potentially in excess of 50%.

Optionally, the one or more light transmissive materials comprise one or more of plastic material, glass and silica.

Optionally, the continuous manufacturing process is one or more of a roll-to-roll process and a web process.

Optionally, the disposing comprises printing at least one of the one or more light sources onto one or more sides of the substrate. For example, OLED devices are now producible in printed form.

Optionally, the method further comprises placing one or more electronic circuit components on one or more sides of the substrate.

Optionally, the placing of the one or more electronic circuit components comprises printing at least one of the one or more electronic circuit components onto the substrate.

Optionally, the molding comprises one or more of a thermoplastic molding, a thermoset molding, an insert molding and a transfer molding.

Optionally, the method further comprises configuring the substrate into one or more physical forms.

Optionally, the method further comprises depositing one or more spectral conversion elements on one or more portions of the one or more integrated light guides.

Optionally, the substrate comprises one or more of a paper, a coated paper, plastics material coated paper, embossed paper, fiber paper, cardboard, poster paper, poster board, wood, plastics material, rubber, fabric, glass and ceramic.

Optionally, at least one of the one or more light sources is proximal to one or more outer boundaries of the one or more integrated light guides.

Optionally, the method further comprises assembling a plurality of the one or more integrated light guides to form a back light for one or more of a Liquid Crystal Display (LCD) device and a plasma display panel (PDP) device.

According to a second aspect, there is provided a system capable of forming one or more integrated light guides comprising one or more light sources and one or more light transmissive materials. At least one of the one or more light transmissive materials is capable of transmitting light emitted by at least one of the one or more light sources. The system includes a disposing unit for disposing the one or more light sources on one or more sides of a substrate to form an arrangement of the one or more light sources. Additionally, the system includes a molding unit for molding the one or more light transmissive materials onto one or more parts of one or more sides of the arrangement of the one or more light sources to form one or more integrated light guides. Further, the system is capable of performing a continuous manufacturing process.

Optionally, the one or more light sources comprise one or more of a Light Emitting Diode (LED), an Organic Light Emitting Diode (OLED), an Organic Light Emitting Transistor (OLET) and a laser diode. Optionally, the one or more light sources include nanostructures, for example, Zinc Oxide nanowires, which can convert electrical power to optical power with a conversion efficiency potentially in excess of 50%.

Optionally, the one or more light transmissive materials comprise one or more of plastics material, glass and silica.

Optionally, the continuous manufacturing process is one or more of a roll-to-roll process and a web process.

Optionally, the disposing unit comprises a printing unit capable of printing at least one of the one or more light sources onto one or more sides of the substrate.

Optionally, the system further comprises a placing unit capable of placing one or more electronic circuit components on one or more sides of the substrate.

Optionally, the placing unit comprises a printing unit capable of printing at least one of the at least one electronic circuit component onto the substrate.

Optionally, the molding unit is capable of performing one or more of a thermoplastic molding, a thermoset molding, an insert molding and a transfer molding.

Optionally, the system further comprises a configuring unit capable of configuring the substrate into one or more physical forms.

Optionally, the system further comprises a depositing unit capable of depositing one or more spectral conversion elements on one or more portions of the one or more integrated light guides.

Optionally, the substrate comprises one or more of a paper, a coated paper, plastics material coated paper, embossed paper, fiber paper, cardboard, poster paper, poster board, wood, rubber, fabric, glass and ceramic.

Optionally, at least one of the one or more light sources is proximal to one or more outer boundaries of the one or more integrated light guides.

Optionally, the system further comprises an assembling unit capable of assembling two or more of the one or more integrated light guides to form a back light for one or more of a Liquid Crystal Display (LCD) device and a plasma display panel (PDP) device. Such Liquid Crystal Display (LCD) device and plasma display panel (PDP) device are suitable for use in manufacturing televisions and computer monitor screens, for example.

According to a third aspect, there are provided one or more integrated light guides formed in accordance with a method pursuant to the first aspect.

It will be appreciated that features of the various embodiments of the invention are susceptible to being combined in various combinations without departing from the scope of the invention as defined by the appended claims.

### DESCRIPTION OF THE DIAGRAMS

Embodiments of the present invention will now be described, by way of example only, with reference to the following diagrams wherein:

FIG. 1 is an illustration of a side view of an arrangement of one or more light sources and a light guide;

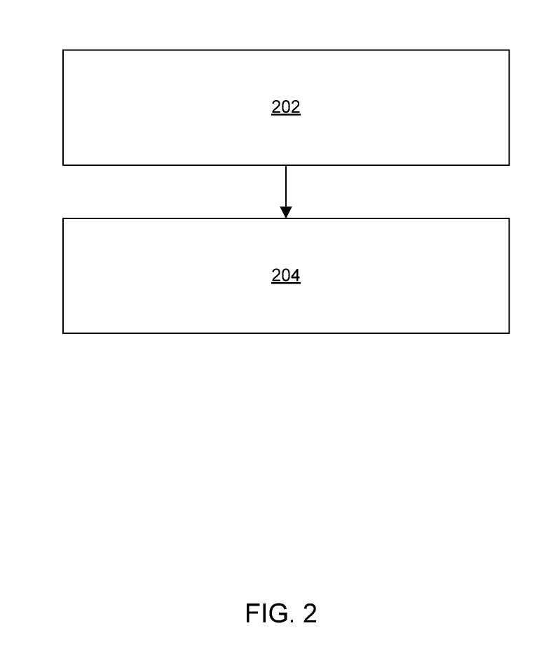

FIG. 2 is an illustration of steps of a method of forming one or more integrated light guides comprising one or more light sources and one or more light transmissive materials pursuant to an embodiment;

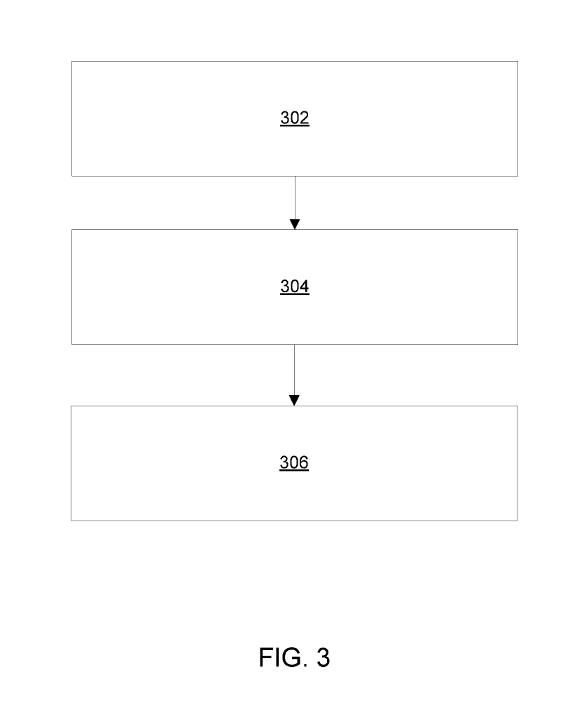

FIG. 3 is an illustration of steps of a method of forming the one or more integrated light guides comprising the one or more light sources and the one or more light transmissive materials pursuant to another embodiment;

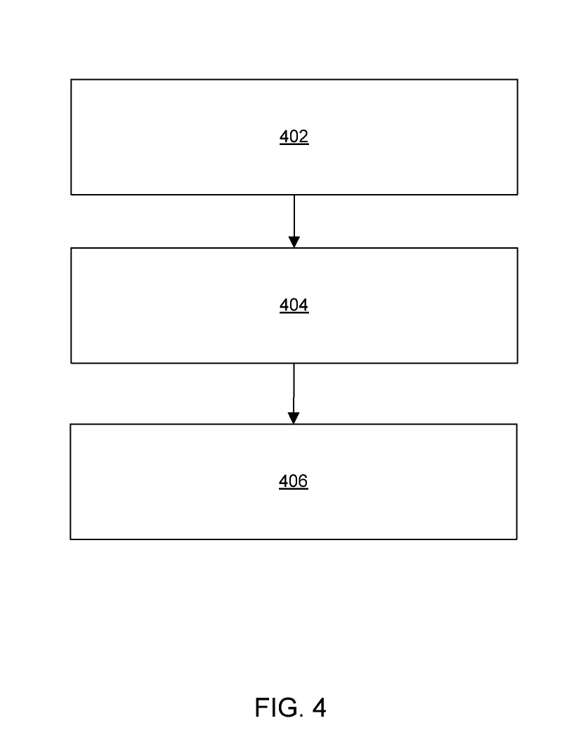

FIG. 4 is an illustration of steps of a method of forming the one or more integrated light guides comprising the one or more light sources and the one or more light transmissive materials pursuant to yet another embodiment;

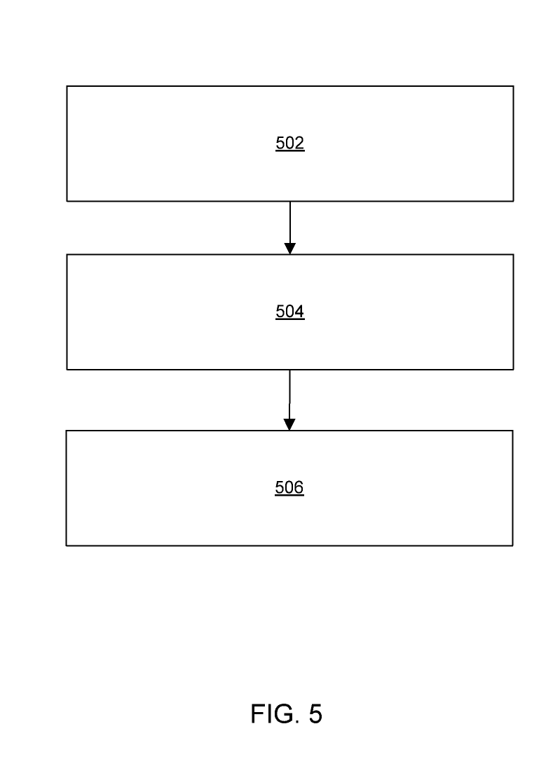

FIG. 5 is an illustration of steps of a method of forming a backlight with two or more integrated light guides comprising the one or more light sources and the one or more light transmissive materials pursuant to yet another embodiment;

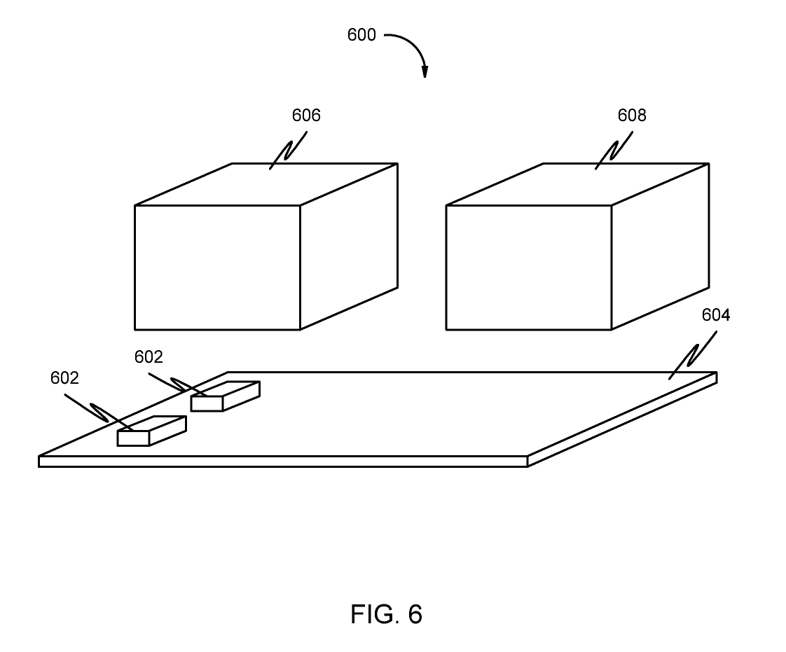

FIG. 6 is an illustration of a side view of a system for forming one or more integrated light guides comprising one or more light sources and one or more light transmissive materials pursuant to an embodiment;

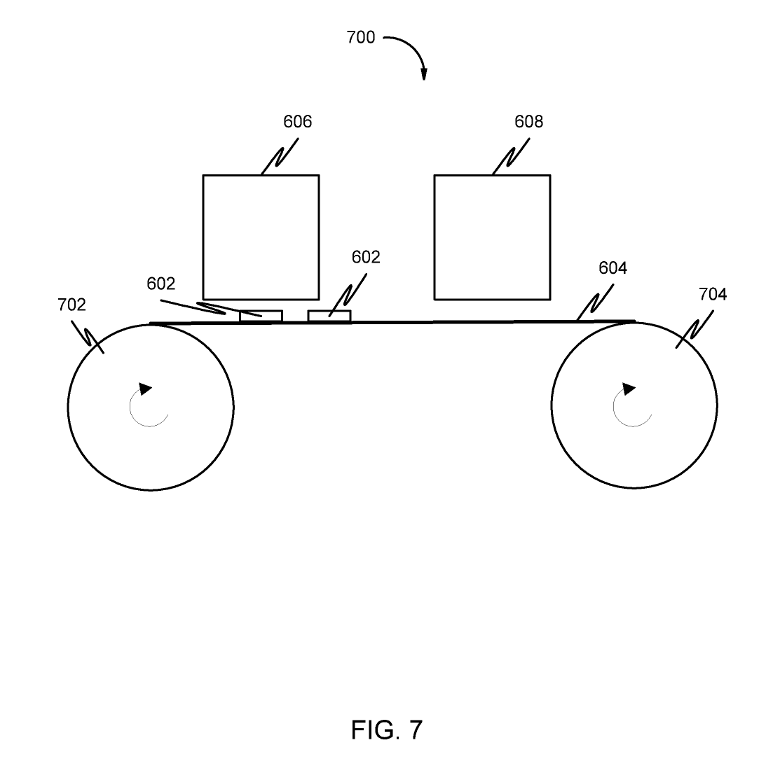

FIG. 7 is an illustration of a side view of a system for forming one or more integrated light guides comprising one or more light sources and one or more light transmissive materials pursuant to another embodiment;

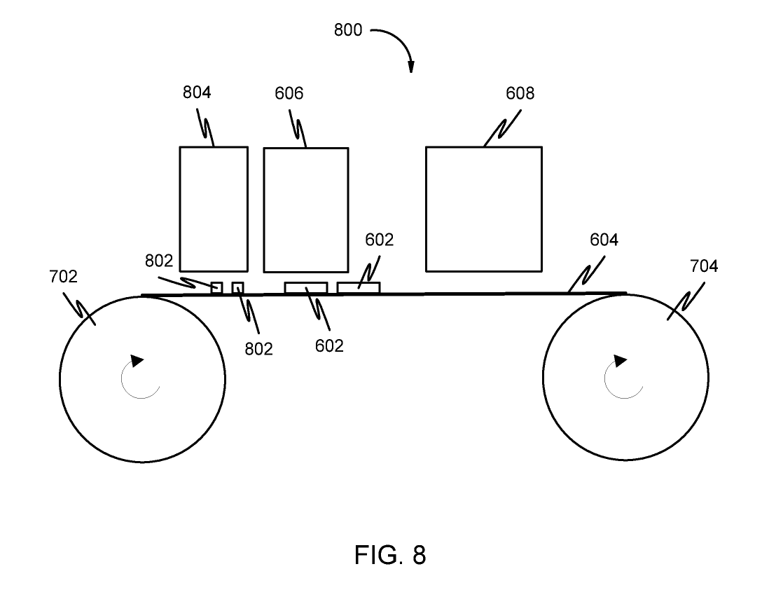

FIG. 8 is an illustration of a side view of a system for forming one or more integrated light guides comprising one or more light sources and one or more light transmissive materials pursuant to yet another embodiment;

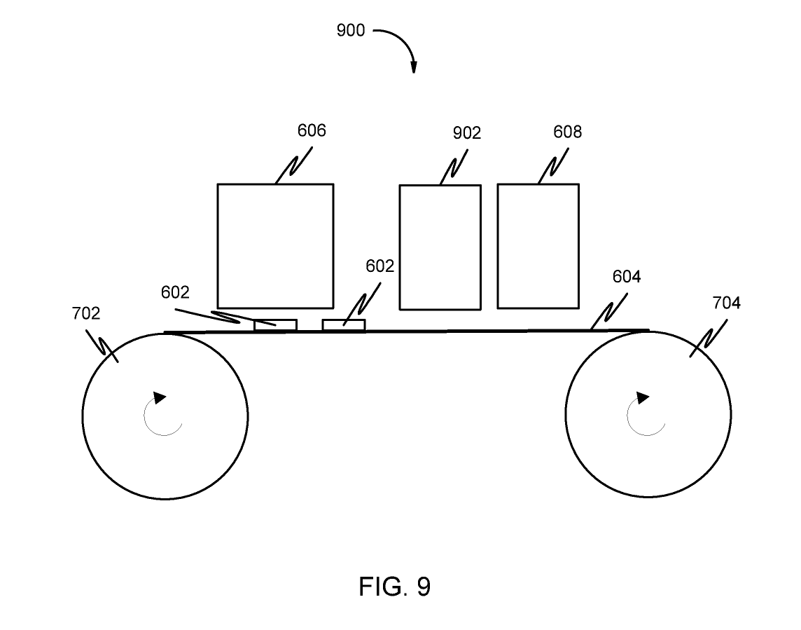

FIG. 9 is an illustration of a side view of a system for forming one or more integrated light guides comprising one or more light sources and one or more light transmissive materials pursuant to still yet another embodiment;

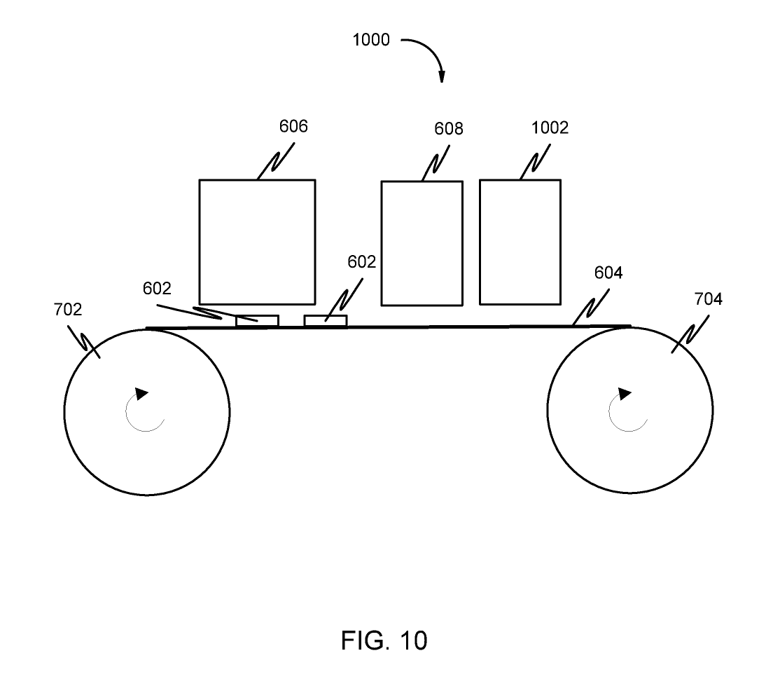

FIG. 10 is an illustration of a side view of a system for forming one or more integrated light guides comprising one or more light sources and one or more light transmissive materials pursuant to still further another embodiment;

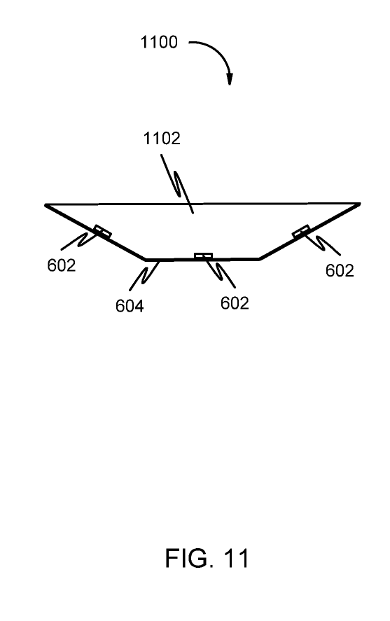

FIG. 11 is an illustration of a side view of an integrated light guide comprising one or more light sources and one or more light transmissive materials pursuant to still further another embodiment; and

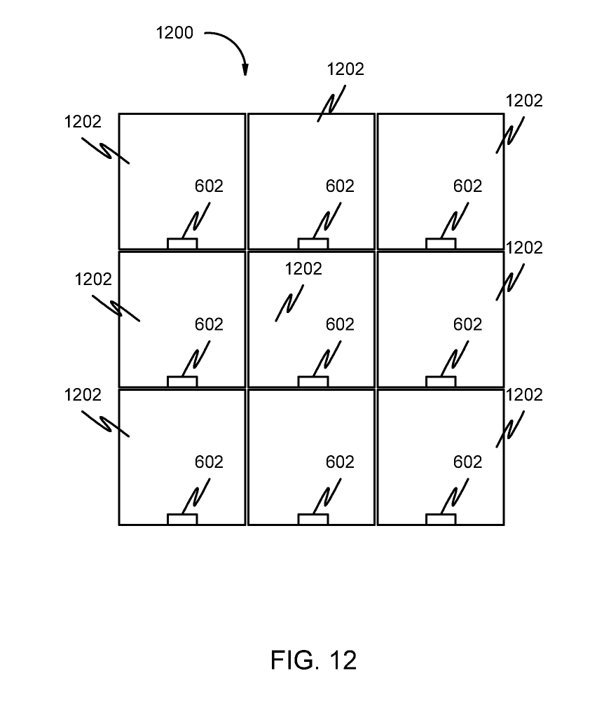

FIG. 12 is an illustration of a top view of an assembly of a plurality of integrated light guides comprising one or more light sources and one or more light transmissive materials pursuant to still further another embodiment.

In the accompanying diagrams, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION

Referring to FIG. 2, steps of a method of forming one or more integrated light guides comprising one or more light sources and one or more light transmissive materials pursuant to an embodiment are illustrated. The one or more light sources include one or more of, but are not limited to, a Light Emitting Diode (LED), an Organic Light Emitting Diode (OLED), an Organic Light Emitting Transistor (OLET) a laser diode and a Cold Cathode Fluorescent Lamp (CCFL). In general, the one or more light sources may include any element capable of emitting electromagnetic radiation. For example, the one or more light sources emit electromagnetic radiation in the form of one or more of infrared radiation, visible radiation and Ultraviolet radiation. Moreover, the one or more light sources may include nanostructures, for example, Zinc Oxide nanowires, which can convert electrical power to optical power with a conversion efficiency potentially in excess of 50%.

The one or more transmissive materials may include one or more of, but are not limited to, a plastics material, glass and silica. The plastics material may be one or more of, but not limited to, Poly Carbonate (PC), Poly Methyl Methacrylate (PMMA), a copolymer of Methyl Methacrylate and Styrene (MS resin) and Polyethylene Terephthalate (PET). The one or more light transmissive materials are capable of transmitting light emanating from the one or more light sources. Accordingly, the one or more light transmissive materials may exhibit a range of transmittances in the range of, but not limited to, 80% to 100%. Furthermore, the one or more transmissive materials may exhibit one or more of homogenic optical characteristics, heterogenic optical characteristics, homogenic mechanical characteristics and heterogenic mechanical characteristics.

The method includes disposing the one or more light sources on one or more sides of a substrate to form an arrangement of the one or more light sources at step 202.

The substrate may include one or more of, but is not limited to, a paper, a coated paper, a plastics material, a coated paper, an embossed paper, a fiber paper, a cardboard, a poster paper, a poster board, wood, rubber, fabric, glass and ceramic. In some embodiments, the substrate may include one or more electronic circuit components on the one or more sides of the substrate. The one or more electronic circuit components may include one or more of, but are not limited to, a conductor, a resistor, a capacitor, an inductor, a semiconductor, an insulator, a diode, a transistor and an Integrated Circuit (IC).

Moreover, the substrate may be in the form of one or more geometric shapes. The one or more geometric shapes may include, but are not limited to, a sheet, a sphere, a cuboid, an ellipsoid, a cylinder and any arbitrary shape. A side of the one or more sides of the substrate may include one or more of, but is not limited to, a superior side, an inferior side, a medial side, a lateral side, an anterior side and a posterior side. In an instance where the substrate is a sheet, the one or more sides of the substrate may include one or more an upper side and a lower side.

Disposing the one or more light sources on one or more sides of the substrate may include one or more of, but not limited to, placing the one or more light sources on the one or more sides of the substrate and embedding the one or more light sources into one or more regions proximal to one or more sides of the substrate. In an instance, placing the one or more light sources may include use of an adhesive material to secure the one or more light sources on the one or more sides of the substrate to form the arrangement of the one or more light sources. The arrangement of the one or more light sources includes one or more of the one or more light sources and one or more parts of the substrate.

Moreover, disposing the one or more light sources on the one or more sides of the substrate may be controlled in order to produce a predetermined spatial pattern of the one or more light sources on the one or more sides of the substrate. For example, the one or more light sources may be disposed on the one or more sides of the substrate to form a spatial pattern comprising the one or more light sources disposed at regular spatial intervals on the one or more sides of the substrate. In some embodiments, at least one of the one or more light sources may disposed in such a manner so as to result in the one or more light sources being proximal to one or more outer boundaries of the one or more integrated light guides.

Furthermore, disposing the one or more light sources on the one or more sides of the substrate may be controlled so as to result in a predetermined orientation of the one or more light sources in relation to the one or more sides of the substrate. In an instance, the predetermined orientation of the one or more light sources may be such that light emanating from the one or more light sources is largely perpendicular to the one or more sides of the substrate. In another instance, the predetermined orientation of the one or more light sources may be such that light emanating from the one or more light sources is largely parallel to the one or more sides of the substrate. In yet another instance, the predetermined orientation of the one or more light sources may be such that light emanating from the one or more light sources is largely in any arbitrary angle in relation to the one or more sides of the substrate.

Moreover, in an embodiment, the one or more light sources may be disposed on the one or more sides of the substrate such that one or more light emitting surfaces of the one or more light sources are not in contact with the one or more sides of the substrate. In another embodiment, the one or more light sources may be disposed on the one or more sides of the substrate such that one or more light emitting surfaces of the one or more light sources are in contact with the one or more sides of the substrate.

In some embodiments, disposing the one or more light sources includes printing at least one of the one or more light sources onto one or more sides of the substrate. The printing may involve forming one or more of conductors, semiconductors and insulators onto the one or more sides of the substrate by directly depositing suitable materials onto one or more sides of the substrate by utilizing one or more printers.

In some other embodiments, disposing the one or more light sources may include forming one or more interconnections among the one or more electronic circuit components and the one or more light sources. The one or more interconnections may be formed utilizing one or more of wire bonding, reflow soldering, wave soldering, flip-chip bonding, Tape Automated Bonding (TAB) and chip-on-board bonding.

Subsequent to disposing the one or more light sources, at step 204, the one or more light transmissive materials are molded onto one or more parts of one or more sides of the arrangement of the one or more light sources to form the one or more integrated light guides. The molding may include one or more of a thermoplastic molding, a thermoset molding, an insert molding and a transfer molding. In order to mold the one or more light transmissive materials onto the one or more parts of one or more sides of the arrangement of the one or more light sources, one or more molds may be utilized. A mold of the one or more molds may include one or more cavities corresponding to one or more of the arrangement of the one or more light sources, one or more geometric shapes corresponding to the substrate and a shape of the one or more integrated light guides. The shape of the one or more integrated light guides may be one or more of a sheet, a sphere, a hemisphere, a cuboid, an ellipsoid, a cylinder and any arbitrary shape. The one or more cavities may be formed in such a manner so as to accommodate one or more of the arrangement of one or more light sources and the one or more geometric shapes corresponding to the substrate. Furthermore, the one or more cavities may be formed in such a manner so as to result in a predetermined physical form of the one or more integrated light guides. Moreover, the one or more cavities may be distributed over one or more of an upper portion of the mold and a lower portion of the mold. In an embodiment, the molding of the one or more light transmissive materials onto the one or more parts of one or more sides of the arrangement of the one or more light sources may be performed utilizing an injection molding process. The injection molding process may begin with placing the arrangement of the one or more light sources inside the one or more molds. Subsequently, the one or more molds may be sealed from surrounding atmosphere and any residual air within the one or more cavities may be removed in order to reduce, preferably minimize, formation of air bubbles in the one or more integrated light guides. Thereafter, a predetermined amount of liquid resin including the one or more light transmissive materials may be injected into the one or more molds at a predetermined injection pressure and a predetermined injection speed. Moreover, the one or more molds may be maintained at a temperature in a range of, but not limited to, 100° C. to 200° C. Furthermore, a holding injection pressure inside the one or more molds may be maintained at a pressure in a range of, but not limited to, 50 psi to 1000 psi, namely 3.4 Bar to 69 Bar. Subsequently, the resin is allowed to cure over a predetermined period of time, for example, about 5 minutes.

Moreover, in some embodiments, one or more of the step 204 and the step 206 may be performed utilizing a continuous manufacturing process. The continuous manufacturing process may be one or more of a roll-to-roll process and a web process. This is explained in detail in conjunction with FIG. 7.

In some embodiments, the method may further include depositing one or more spectral conversion elements on one or more portions of the one or more integrated light guides. The one or more portions may include, for example, but are not limited to, one or more outer surfaces of the one or more integrated light guides. The one or more spectral conversion elements are characterized by a property of absorbing electromagnetic radiation at one or more wavelengths and subsequently emitting electromagnetic radiation at one or more other wavelengths. The one or more spectral conversion elements may be, for example, but are not limited to one or more of Yttrium Aluminum Garnet (YAG) phosphor, Cerium doped Yttrium Aluminum garnet (YAG:Ce) phosphor, blue phosphor, red phosphor and green phosphor.

FIG. 3 is an illustration of steps of a method for forming the one or more integrated light guides comprising the one or more light sources and the one or more light transmissive materials pursuant to another embodiment. At step 302, one or more electronic circuit components are placed on one or more sides of the substrate. The one or more electronic circuit components may include one or more of, but are not limited to, a conductor, a resistor, a capacitor, an inductor, a semiconductor, an insulator, a diode, a transistor and an Integrated Circuit (IC). In an embodiment, the one or more electronic circuit components may be placed by printing at least one of the one or more electronic circuit components onto the one or more sides of the substrate. For example, the printing may be performed by directly depositing suitable materials onto the one or more sides of the substrate by utilizing one or more printers. In another embodiment, the one or more electronic circuit components may be placed by utilizing one or more of wire bonding, reflow soldering, wave soldering, flip-chip bonding, Tape Automated Bonding (TAB) and chip-on-board bonding.

Subsequently, at step 304, the one or more light sources are disposed on the one or more sides of a substrate to form an arrangement of the one or more light sources. Details about disposing the one or more light sources are described in conjunction with FIG. 2. Moreover, in some embodiments, disposing the one or more light sources may include forming one or more interconnections among the one or more electronic circuit components and the one or more light sources. The one or more interconnections may be formed utilizing one or more of wire bonding, reflow soldering, wave soldering, flip-chip bonding, Tape Automated Bonding (TAB) and chip-on-board bonding.

Thereafter, at step 306, the one or more light transmissive materials are molded onto one or more parts of one or more sides of the arrangement of the one or more light sources to form the one or more integrated light guides. Details about molding the one or more light transmissive materials are described in conjunction with FIG. 2. Furthermore, in some embodiments, the molding may be performed such that one or more of the one or more electronic components and the one or more interconnections are completely embedded in the one or more light transmissive materials. Accordingly, the one or more cavities of the one or more molds may be configured. In other embodiments, the molding may be performed such that one or more of the one or more electronic components and the one or more interconnections are partially embedded in the one or more light transmissive materials. In yet other embodiments, the molding may be performed such that one or more of the one or more electronic components and the one or more interconnections are not embedded in the one or more light transmissive materials. Optionally, the molding is performed using the one or more light transmissive materials exhibiting spatially homogenic optical characteristics. Alternatively, the molding is performed using one or more light transmissive materials exhibiting spatially heterogenic optical characteristics, for example for forming in a synergistic manner optical refractive components within the molding. Optionally, the one or more light transmissive materials in a spatial proximity of the one or more light sources is elastically compliant, for example, for providing mechanical stress relief for the one or more light sources, whilst enabling a remainder of the molding remote from the one or more light sources to be mechanically rigid for maintaining structural stability. Such spatially graded mechanical properties of the one or more light transmissive materials can, for example, be achieved by employing multiple plastics material injectors supplied with mutually different light transmitting materials, wherein the injected plastics materials are concurrently molded and are allowed to diffuse at boundaries therebetween for avoiding a formation of abrupt optical boundaries in a final product whereat undesirable reflections would otherwise arise.

Although FIG. 3 illustrates the method in a sequence comprising the step 302, the step 304 and the step 306, a person skilled in the art will appreciate that the method may be performed in any other sequence comprising the step 302, the step 304 and the step 306. For example, in an embodiment, the step 304 may be performed prior to performing the step 302. Similarly, in another embodiment, the step 302 may be performed after performing the step 306.

Moreover, in some embodiments, one or more of the step 302, the step 304, and the step 306 may be performed utilizing a continuous manufacturing process. The continuous manufacturing process may be one or more of a roll-to-roll process and a web process.

FIG. 4 is an illustration of steps of a method for forming the one or more integrated light guides comprising the one or more light sources and the one or more light transmissive materials pursuant to another embodiment. At step 402, the one or more light sources are disposed on one or more sides of a substrate to form an arrangement of the one or more light sources. Details about disposing the one or more light sources are described in conjunction with FIG. 2.

Subsequently, at step 404, the substrate is configured into one or more physical forms. The one or more physical forms may correspond to the shape of the one or more integrated light guides. The shape of the one or more integrated light guides may be one or more of a sheet, a sphere, a hemisphere, a cuboid, an ellipsoid, a cylinder and any arbitrary shape. For example, FIG. 11 illustrates a trapezoidal shape of an integrated light guide of the one or more integrated light guides.

Thereafter, at step 406, the one or more light transmissive materials are molded onto one or more parts of one or more sides of the arrangement of the one or more light sources to form the one or more integrated light guides. Details about molding the one or more light transmissive materials are described in conjunction with FIG. 2.

Although FIG. 4 illustrates the method in a sequence comprising the step 402, the step 404 and the step 406, a person skilled in the art will appreciate that the method may be performed in any other sequence comprising the step 402, the step 404 and the step 406. For example, in an embodiment, the step 404 may be performed prior to performing the step 402. Similarly, in another embodiment, the step 404 may be performed after performing the step 406.

Moreover, in some embodiments, one or more of the step 402, the step 404, and the step 406 may be performed utilizing a continuous manufacturing process. The continuous manufacturing process may be one or more of a roll-to-roll process and a web process.

FIG. 5 is an illustration of steps of a method for forming a backlight with two or more integrated light guides of the one or more integrated light guides comprising the one or more light sources and the one or more light transmissive materials pursuant to yet another embodiment. The backlight may be used in an application where a predetermined spatial distribution of light is required. For example, the backlight may be used in a non-emissive display device, such as a Liquid Crystal Display (LCD) device and a plasma display panel (PDP) device. Such Liquid Crystal Display (LCD) device and plasma display panel (PDP) device are suitable for use in manufacturing televisions and computer monitor screens, for example. At step 502, the one or more light sources are disposed on one or more sides of a substrate to form an arrangement of the one or more light sources. Details about disposing the one or more light sources are described in conjunction with FIG. 2. Subsequently, at step 504, the one or more light transmissive materials are molded onto one or more parts of one or more sides of the arrangement of the one or more light sources to form the one or more integrated light guides. Details about molding the one or more light transmissive materials are described in conjunction with FIG. 2. Thereafter, at step 506, two or more of the one or more integrated light guides are assembled to form the back light. Assembling the two or more integrated light guides may involve placing the two or more integrated light guides in a predetermined spatial pattern. For example, the FIG. 12 illustrates one such assembly of the two or more integrated light guides.

In some embodiments, one or more of the step 502, the step 504, and the step 506 may be performed utilizing a continuous manufacturing process. The continuous manufacturing process may be one or more of a roll-to-roll process and a web process.

FIG. 6 is an illustration of a side view of a system 600 for forming one or more integrated light guides comprising one or more light sources 602 and one or more light transmissive materials pursuant to an embodiment. The one or more light sources 602 include one or more of, but are not limited to, a Light Emitting Diode (LED), an Organic Light Emitting Diode (OLED), an Organic Light Emitting Transistor (OLET) a laser diode and a Cold Cathode Fluorescent Lamp (CCFL). In general, the one or more light sources 602 may include any element capable of emitting electromagnetic radiation. For example, the one or more light sources 602 emit electromagnetic radiation in the form of one or more of infrared radiation, visible radiation and Ultraviolet radiation. Moreover, the one or more light sources include nanostructures, for example, Zinc Oxide nanowires, which can convert electrical power to optical power with a conversion efficiency potentially in excess of 50%.

The one or more transmissive materials may include one or more of, but are not limited to, a plastics material, glass and silica. The plastics material may be one or more of, but not limited to, Poly Carbonate (PC), Poly Methyl Methacrylate (PMMA), a copolymer of Methyl Methacrylate and Styrene (MS resin) and Polyethylene Terephthalate (PET). The one or more light transmissive materials are capable of transmitting light emanating from the one or more light sources 602. Accordingly, the one or more light transmissive materials may exhibit a range of transmittances in the range of, but not limited to, 80% to 100%. Furthermore, the one or more transmissive materials may exhibit one or more of homogenic optical characteristics, heterogenic optical characteristics, homogenic mechanical characteristics and heterogenic mechanical characteristics.

The system 600 comprises each of a disposing unit 606 and a molding unit 608. The disposing unit 602 is capable of disposing the one or more light sources 602 on one or more sides of a substrate 604 to form an arrangement of the one or more light sources.

The substrate 604 may include one or more of, but is not limited to, a paper, a coated paper, a plastics material, a coated paper, an embossed paper, a fiber paper, a cardboard, a poster paper, a poster board, wood, rubber, fabric, glass and ceramic. In some embodiments, the substrate 604 may include one or more electronic circuit components on the one or more sides of the substrate 604. The one or more electronic circuit components may include one or more of, but are not limited to, a conductor, a resistor, a capacitor, an inductor, a semiconductor, an insulator, a diode, a transistor and an Integrated Circuit (IC). Furthermore, the substrate 604 may be in the form of one or more geometric shapes. The one or more geometric shapes may include, but are not limited to, a sheet, a sphere, a cuboid, an ellipsoid, a cylinder and any arbitrary shape. A side of the one or more sides of the substrate 604 may include one or more of, but is not limited to, a superior side, an inferior side, a medial side, a lateral side, an anterior side and a posterior side. In an instance where the substrate 604 is a sheet, the one or more sides of the substrate 604 may include one or more an upper side and a lower side.

The disposing unit 606 may be capable of disposing the one or more light sources 602 on one or more sides of the substrate 604 by one or more of, but not limited to, placing the one or more light sources 602 on the one or more sides of the substrate 604 and embedding the one or more light sources 602 into one or more regions proximal to one or more sides of the substrate 604. In an instance, the disposing unit 606 may be capable of placing the one or more light sources 602 by using an adhesive material to secure the one or more light sources 602 on the one or more sides of the substrate 604, to form the arrangement of the one or more light sources. The arrangement of the one or more light sources 602 includes one or more of the one or more light sources 602 and one or more parts of the substrate 604.

Further, the disposing unit 606 may be capable of controlling the disposing of the one or more light sources 602 on the one or more sides of the substrate 604 in order to produce a predetermined spatial pattern of the one or more light sources 602 on the one or more sides of the substrate 604. For example, the disposing unit 606 may be capable of disposing the one or more light sources 602 on the one or more sides of the substrate 604 to form a spatial pattern comprising the one or more light sources 602 disposed at regular spatial intervals on the one or more sides of the substrate 604. In some embodiments, the disposing unit 606 may be capable of disposing the at least one of the one or more light sources 602 in such a manner so as to result in the one or more light sources 602 being proximal to one or more outer boundaries of the one or more integrated light guides.

Furthermore, the disposing unit 606 may be capable of controlling the disposing of the one or more light sources 602 on the one or more sides of the substrate 604 so as to result in a predetermined orientation of the one or more light sources 602 in relation to the one or more sides of the substrate 604. In an instance, the predetermined orientation of the one or more light sources 602 may be such that light emanating from the one or more light sources 602 is largely perpendicular to the one or more sides of the substrate 604. In another instance, the predetermined orientation of the one or more light sources 602 may be such that light emanating from the one or more light sources 602 is substantially parallel to the one or more sides of the substrate 604. In yet another instance, the predetermined orientation of the one or more light sources 602 may be such that light emanating from the one or more light sources 602 is substantially in any arbitrary angle in relation to the one or more sides of the substrate 604.

Moreover, in an embodiment, the disposing unit 606 may be capable of disposing the one or more light sources 602 on the one or more sides of the substrate 604 such that one or more light emitting surfaces of the one or more light sources 602 are not in contact with the one or more sides of the substrate 604. In another embodiment, the disposing unit 606 may be capable disposing the one or more light sources 602 on the one or more sides of the substrate 604 such that one or more light emitting surfaces of the one or more light sources 602 are in contact with the one or more sides of the substrate 604.

In some embodiments, the disposing unit 606 may include a printing unit capable of printing at least one of the one or more light sources 602 onto one or more sides of the substrate 604. The printing unit may be capable of forming one or more of conductors, semiconductors and insulators onto the one or more sides of the substrate 604 by directly depositing suitable materials onto one or more sides of the substrate 604 by utilizing one or more printers.

In some embodiments, the disposing unit 606 may be capable of forming one or more interconnections among the one or more electronic circuit components and the one or more light sources 602. The one or more interconnections may be formed utilizing one or more of wire bonding, reflow soldering, wave soldering, flip-chip bonding, Tape Automated Bonding (TAB) and chip-on-board bonding.

The molding unit 608 is capable of molding the one or more light transmissive materials onto one or more parts of one or more sides of the arrangement of the one or more light sources 602 to form the one or more integrated light guides. The molding unit 608 may be capable of performing one or more of a thermoplastic molding, a thermoset molding, an insert molding and a transfer molding. In order to mold the one or more light transmissive materials onto the one or more parts of one or more sides of the arrangement of the one or more light sources, the molding unit 608 may include one or more molds. A mold of the one or more molds may include one or more cavities corresponding to one or more of the arrangement of the one or more light sources, one or more geometric shapes corresponding to the substrate 604 and a shape of the one or more integrated light guides. The shape of the one or more integrated light guides may be one or more of a sheet, a sphere, a hemisphere, a cuboid, an ellipsoid, a cylinder and any arbitrary shape. The one or more cavities may be formed in such a manner so as to accommodate one or more of the arrangement of one or more light sources 602 and the one or more geometric shapes corresponding to the substrate 604. Further, the one or more cavities may be formed in such a manner so as to result in a predetermined physical form of the one or more integrated light guides. Moreover, the one or more cavities may be distributed over one or more of an upper portion of the mold and a lower portion of the mold.

In an embodiment, the molding unit 608 may be capable of molding the one or more light transmissive materials onto the one or more parts of one or more sides of the arrangement of the one or more light sources 602 by utilizing an injection molding process. The molding unit 608 may be capable of placing the arrangement of the one or more light sources 602 inside the one or more molds. Furthermore, the molding unit 608 may be capable of sealing the one or more molds from surrounding atmosphere and capable of removing any residual air within the one or more cavities in order to minimize formation of air bubbles in the one or more integrated light guides. Furthermore, the molding unit 608 may be capable of injecting a predetermined amount of liquid resin including the one or more light transmissive materials into the one or molds at a predetermined injection pressure and a predetermined injection speed. Further yet, the molding unit 608 may be capable of maintaining the one or more molds at a temperature in a range of, but not limited to, 100° C. to 200° C. Moreover, the molding unit 608 may be capable of maintaining a holding injection pressure inside the one or more molds at a pressure in a range of, but not limited to, 50 psi and 1000 psi, namely 3.4 Bar to 69 Bar. Additionally, the molding unit 608 may be capable of curing the resin over a predetermined period of time, for example, about 5 minutes.

In some embodiments, the system 600 may include a depositing unit capable of depositing one or more spectral conversion elements on one or more portions of the one or more integrated light guides. The one or more portions may include, for example, but are not limited to, one or more outer surfaces of the one or more integrated light guides. The one or more spectral conversion elements are characterized by a property of absorbing electromagnetic radiation at one or more wavelengths and subsequently emitting electromagnetic radiation at at least one or more other wavelengths. The one or more spectral conversion elements may be, for example, but are not limited to one or more of Yttrium Aluminum Garnet (YAG) phosphor, Cerium doped Yttrium Aluminum garnet (YAG:Ce) phosphor, blue phosphor, red phosphor and green phosphor.

In an embodiment, the system 600 is capable of performing the method described in conjunction with FIG. 2.

FIG. 7 is an illustration of a side view of a system 700 for forming one or more integrated light guides comprising one or more light sources 602 and one or more light transmissive materials pursuant to another embodiment. In this embodiment, the system 700 is capable of forming the one or more integrated light guides by utilizing a continuous manufacturing process such as a roll-to-roll process.

The system 700 includes each of one or more supply spools 702 and one or more take up spools 704. The substrate 604 may be wound in one or more of at least one of the one or more supply spools 702 and at least one of the one or more take up spools 704. Moreover, the system 700 may be capable of imparting controlled rotary motion to one or more of at least one of the one or more supply spools 702 and at least one of the one or more take up spools 704. As a result, the substrate 604 may be drawn from at least one of the one or more supply spools 702 and wound onto at least one of the one or more take up spools 704.

Further, the system 700 includes each of the disposing unit 606 and the molding unit 608. Details about each of the disposing unit 606 and the molding unit 608 are described in conjunction with FIG. 6.

In an embodiment, the system 700 is capable of performing the method described in conjunction with FIG. 2.

FIG. 8 is an illustration of a side view of a system 800 for forming one or more integrated light guides comprising the one or more light sources 602 and one or more light transmissive materials pursuant to another embodiment. The system 800 includes each of one or more supply spools 702, one or more take up spools 704, a placing unit 804, the disposing unit 606 and the molding unit 608.

The substrate 604 may be wound in one or more of at least one of the one or more supply spools 702 and at least one of the one or more take up spools 704. Furthermore, the system 700 may be capable of imparting controlled rotary motion to one or more of at least one of the one or more supply spools 702 and at least one of the one or more take up spools 704. As a result, the substrate 604 may be drawn from at least one of the one or more supply spools 702 and wound onto at least one of the one or more take up spools 704.

The placing unit 804 is capable placing one or more electronic circuit components 802 on one or more sides of the substrate 604. The one or more electronic circuit components 802 may include one or more of, but are not limited to, a conductor, a resistor, a capacitor, an inductor, a semiconductor, an insulator, a diode, a transistor and an Integrated Circuit (IC). In an embodiment, the placing unit 802 includes one or more printing units, wherein the one or more printing units may be capable of printing at least one of the one or more electronic circuit components 802 onto the one or more sides of the substrate 604. For example, the printing units may be capable of printing by directly depositing suitable materials onto the one or more sides of the substrate by utilizing one or more printers. In another embodiment, the placing unit 802 may be capable of placing the one or more electronic circuit components 802 by utilizing one or more of wire bonding, reflow soldering, wave soldering, flip-chip bonding, Tape Automated Bonding (TAB) and chip-on-board bonding.

Details about each of the disposing unit 606 and the molding unit 608 are described in conjunction with FIG. 6.

In an embodiment, the system 800 is capable of performing the method described in conjunction with FIG. 3.

FIG. 9 is an illustration of a side view of a system 900 for forming one or more integrated light guides comprising the one or more light sources 602 and one or more light transmissive materials pursuant to another embodiment. The system 900 includes each of one or more supply spools 702, one or more take up spools 704, a configuring unit 902, the disposing unit 606 and the molding unit 608.

The substrate 604 may be wound in one or more of at least one of the one or more supply spools 702 and at least one of the one or more take up spools 704. Furthermore, the system 700 may be capable of imparting controlled rotary motion to one or more of at least one of the one or more supply spools 702 and at least one of the one or more take up spools 704. As a result, the substrate 604 may be drawn from at least one of the one or more supply spools 702 and wound onto at least one of the one or more take up spools 704.

The configuring unit 902 is capable of configuring the substrate into one or more physical forms. The one or more physical forms may correspond to the shape of the one or more integrated light guides. The shape of the one or more integrated light guides may be one or more of a sheet, a sphere, a hemisphere, a cuboid, an ellipsoid, a cylinder and any arbitrary shape. For example, FIG. 11 illustrates a trapezoidal shape of an integrated light guide of the one or more integrated light guides.

Details about each of the disposing unit 606 and the molding unit 608 are described in conjunction with FIG. 6.

In an embodiment, the system 900 is capable of performing the method described in conjunction with FIG. 4.

FIG. 10 is an illustration of a side view of a system 1000 for forming a backlight with two or more integrated light guides of the one or more integrated light guides comprising the one or more light sources 602 and the one or more light transmissive materials pursuant to yet another embodiment. The backlight may be used in an application where a predetermined spatial distribution of light is required. For example, the backlight may be used in a non-emissive display device, such as a Liquid Crystal Display (LCD) device and a plasma display panel (PDP) device.

The system 1000 includes each of the one or more supply spools 702, the one or more take up spools 704, the disposing unit 606, the molding unit 608 and the assembling unit 1002.

The substrate 604 may be wound in one or more of at least one of the one or more supply spools 702 and at least one of the one or more take up spools 704. Further, the system 700 may be capable of imparting controlled rotary motion to one or more of at least one of the one or more supply spools 702 and at least one of the one or more take up spools 704. As a result, the substrate 604 may be drawn from at least one of the one or more supply spools 702 and wound onto at least one of the one or more take up spools 704.

Details about each of the disposing unit 606 and the molding unit 608 are described in conjunction with FIG. 6.

The assembling unit 1002 is capable of assembling two or more of the one or more integrated light guides to form the back light. Further, the assembling unit may be capable of assembling the two or more integrated light guides by placing the two or more integrated light guides in a predetermined spatial pattern. For example, FIG. 12 illustrates one such assembly of the two or more integrated light guides.

In an embodiment, the system 1000 is capable of performing the method described in conjunction with FIG. 5.

FIG. 11 is an illustration of a side view of an integrated light guide 1100 of the one or more integrated light guides comprising the one or more light sources 602 and one or more light transmissive materials 1102 pursuant to a still further another embodiment. The integrated light guide 1100 may be formed in accordance with one or more of one or more of the methods described in conjunction with FIG. 2 to FIG. 5 and one or more systems described in conjunction with FIG. 6 to FIG. 10. As depicted, the substrate 604 may be configured into a shape such as a portion of a trapezoidal. In some embodiments, the substrate 604 may be discarded subsequent to the formation of the integrated light guide 1100. In other embodiments, the substrate 604 may be present along with the integrated light guide 1100 while the integrated light guide 1100 is in use.

FIG. 12 is an illustration of a top view of an assembly 1200 of two or more integrated light guides of the one or more integrated light guides comprising one or more light sources 602 and one or more light transmissive materials 1202 pursuant to still further another embodiment. The assembly 1200 of the two or more integrated light guides may be formed in accordance with one or more of one or more of the methods described in conjunction with FIG. 2 to FIG. 5 and one or more systems described in conjunction with FIG. 6 to FIG. 10. The assembly 1200 may be used to form a back light for one or more of a Liquid Crystal Display (LCD) device and a plasma display panel (PDP).

In some embodiments, the one or more integrated light guides formed in accordance with one or more of one or more of the methods described in conjunction with FIG. 2 to FIG. 5 and one or more systems described in conjunction with FIG. 6 to FIG. 10 may be used in a touch screen device, wherein the touch screen device may be part of, for example, a mobile device.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural. Numerals included within parentheses in the accompanying claims are intended to assist understanding of the claims and should not be construed in any way to limit subject matter claimed by these claims.

We claim:

1. A method of forming at least one integrated light guide, the at least one integrated light guide comprising at least one light source and at least one light transmissive material, wherein at least one of the at least one light transmissive material is capable of guiding light emitted by at least one of the at least one light source,
wherein the method comprises:
disposing the at least one light source on at least one side of a substrate to form an arrangement of the at least one light source;
molding the at least one light transmissive material onto at least a part of at least one side of the arrangement of the at least one light source to form the at least one integrated light guide; and
performing the method utilizing a continuous manufacturing process.

2. The method as claimed in claim 1, wherein the at least one light source comprises one or more of a Light Emitting Diode (LED), an Organic Light Emitting Diode (OLED), an Organic Light Emitting Transistor (OLET) and a laser diode.

3. The method as claimed in claim 1, wherein the at least one light transmissive material comprises at least one of plastics material, glass and silica.

4. The method as claimed in claim 1, wherein the continuous manufacturing process is one or more of a roll-to-roll process and a web process.

5. The method as claimed in claim 1, wherein the disposing comprises printing at least one of the at least one light source onto at least one side of the substrate.

6. The method as claimed in claim 1, wherein at least one of the at least one light source is proximal to at least one outer boundary of the at least one integrated light guide.

7. The method as claimed in claim 1, further comprising assembling a plurality of the at least one integrated light guide to form a back light for at least one of a Liquid Crystal Display (LCD) device and a plasma display panel (PDP) device.

8. A system for forming at least one integrated light guide, the at least one integrated light guide comprising at least one light source and at least one light transmissive material, wherein at least one of the at least one light transmissive material is capable of guiding light emitted by at least one of the at least one light source,
wherein the system comprises:
a disposing unit for disposing the at least one light source on at least one side of a substrate to form an arrangement of the at least one light source;
a molding unit for molding the at least one light transmissive material onto at least a part of at least one side of the arrangement of the at least one light source to form at least one integrated light guide; and
a continuous manufacturing process

9. The system as claimed in claim 8, wherein the at least one light source comprises one or more of a Light Emitting Diode (LED), an Organic Light Emitting Diode (OLED), an Organic Light Emitting Transistor (OLET) and a laser diode.

10. The system as claimed in claim 8, wherein the at least one light transmissive material comprises at least one of plastics material, glass and silica.

11. The system as claimed in claim 8, wherein the continuous manufacturing process is one or more of a roll-to-roll process and a web process.

12. The system as claimed in claim 8, wherein the disposing unit comprises a printing unit capable of printing at least one of the at least one light source onto at least one side of the substrate.

13. The system as claimed in claim 8, wherein at least one of the at least one light source is proximal to at least one outer boundary of the at least one integrated light guide.

14. The system as claimed in claim 8, further comprising an assembling unit capable of assembling a plurality of the at least one integrated light guide to form a back light for at least one of a Liquid Crystal Display (LCD) device and a plasma display panel (PDP) device.

15. A integrated light guide comprising at least one light source and at least one light transmissive material, wherein at least one of the at least one light transmissive material is capable of guiding light emitted by at least one of the at least one light source,
wherein the integrated light guide is formed by a method comprising:
disposing the at least one light source on at least one side of a substrate to form an arrangement of the at least one light source;
molding the at least one light transmissive material onto at least a part of at least one side of the arrangement of the at least one light source to form at least one integrated light guide; and
performing the method utilizing a continuous manufacturing process.

16. The integrated light guide as claimed in claim 15, wherein the at least one light source comprises one or more of a Light Emitting Diode (LED), an Organic Light Emitting Diode (OLED), an Organic Light Emitting Transistor (OLET) and a laser diode.

17. The integrated light guide as claimed in claim 15, wherein the at least one light transmissive material comprises at least one of plastics material, glass and silica.

18. The integrated light guide as claimed in claim 15, wherein the continuous manufacturing process is one or more of a roll-to-roll process and a web process.

19. The integrated light guide as claimed in claim 15, wherein the disposing comprises printing at least one of the at least one light source onto at least one side of the substrate.

20. The integrated light guide as claimed in claim 15, wherein the method further comprises placing at least one electronic circuit component on at least one side of the substrate.

21. The integrated light guide as claimed in claim 20, wherein the placing comprises printing at least one of the at least one electronic circuit component onto at least one side of the substrate.

22. The integrated light guide as claimed in claim 15, wherein the method further comprises assembling a plurality of the at least one integrated light guide to form a back light for at least one of a Liquid Crystal Display (LCD) device and a plasma display panel (PDP) device.

23. A touch-screen device comprising at least one integrated light guide as claimed in claim 15.
